(19) United States
(12) Patent Application Publication
(10) Pub. No.: US 2022/0035013 A1
(43) Pub. Date: Feb. 3, 2022

(54) FAST NUMERICAL SIMULATION METHOD FOR LASER RADAR RANGING CONSIDERING SPEED FACTOR

(71) Applicant: ZHEJIANG LAB, Hangzhou City (CN)

(72) Inventors: Wei HUA, Hangzhou City (CN); Jianjian GAO, Hangzhou City (CN); Tian XIE, Hangzhou City (CN); Rong LI, Hangzhou City (CN)

(21) Appl. No.: 17/412,188

(22) Filed: Aug. 25, 2021

Related U.S. Application Data
(63) Continuation of application No. PCT/CN2020/110859, filed on Aug. 24, 2020.

(30) Foreign Application Priority Data
Jul. 30, 2020 (CN) 202010750633.X

(51) Int. Cl. G01S 7/497; G01S 17/08; G01S 17/42

(52) U.S. Cl. CPC G01S 7/497; G01S 17/42; G01S 17/08

(57) ABSTRACT

The present disclosure relates to a fast numerical simulation method for laser radar ranging considering a speed factor. According to the method, the motion of the laser radar itself and the motion of an object in the surrounding environment are fully considered in the simulation process. The motion of the laser radar itself not only includes the overall motion of the device, but also includes the rotary scanning motion of a laser emitter, so that accurate numerical simulation is provided. In addition, the amount of calculation is simplified by introducing a sampling point set, and the effect of improving the accuracy of simulation by using a small amount of calculation is achieved. The method is especially suitable for a scenario where the laser radar itself and/or surrounding objects are in a high-speed motion state, and can achieve a significantly higher simulation precision than that achieved by existing methods.

### TECHNICAL FIELD

The present disclosure relates to the field of numerical simulation of laser radar ranging, and particularly to a fast numerical simulation method for laser radar ranging considering a speed factor.

### BACKGROUND

Autonomous driving simulation technology, especially vehicle sensor simulation technology, has always been one of the technical focuses in the field of autonomous driving. Among others, the simulation of laser radar is an indispensable and important part.

There are a variety of laser radar simulation methods. For example, Huang Xi et al. proposed a ray tracing-based laser radar simulation method in Chinese Patent application No. CN104268323A. This method generates simulation images with a sense of physical reality by simulating the reflection trajectory of laser rays. In Chinese Patent application No. CN107966693A, Su Hu et al. proposed a deep-rendering-based vehicle-mounted laser radar simulation method. This method periodically performs depth rendering of the fan-shaped area of the testing scene to obtain simulation images. However, such methods are not precise enough to simulate the movement and scanning process of the laser radar itself, as well as the movement of the objects in the scene. In such simulation process, laser lights emitted by the laser radar in various directions during a period of time are considered to be simultaneously emitted at a certain moment, and all objects in the scene remain stationary relative to the laser radar during this period of time. This is inconsistent with the actual working principle of laser radar, which will lead to simulation errors.

### SUMMARY

In view of the disadvantages existing in the prior art, an object of the present disclosure is to provide a fast numerical simulation method for laser radar ranging considering a speed factor. This method takes into consideration the movement of surrounding objects relative to the laser emitter and the scanning and rotation mode of the laser emitter itself in the simulation, maintains the high efficiency of the calculation process by sampling and dynamically updating the scene, and well balances the simulation accuracy and the simulation efficiency.

The objects of the present disclosure are accomplished through the following technical solutions. A fast numerical simulation method for laser radar ranging considering a speed factor, including the following steps:

(1) assuming that a mechanical rotary laser radar to be simulated is Lidar, setting a working mode and parameters of Lidar as follows: Lidar comprises NL laser emitters, the laser emitters are configured to synchronously emit laser rays at a frequency f, each laser emitter emits one laser ray, starting points of the beams are a same point on the Lidar which is defined as a reference point, all the laser emitters are configured for fixed-axis rotation about a straight line passing through the reference point, and the straight line is defined as a rotation axis; a plane perpendicular to the rotation axis is a reference plane, and NL laser rays emitted by the laser emitters at the same moment are located in a plane perpendicular to the reference plane; a direction of either side of the rotation axis is taken as a rotation axis direction, and angles formed by the NL laser rays and the rotation axis direction are successively Θ₀, Θ₁, Θ₂, Θ_{NL-1}, which satisfy Θᵢ<Θⱼ, 0<=i<j<NL; vertical projections of the laser rays emitted by Lidar at a starting moment of each scan cycle on the reference plane coincide with a ray emitted from the reference point, the ray emitted from the reference point is defined as a reference line, an angle by which the laser emitter rotate in a scan cycle T is Φₘₐₓ=ωT, where ω is a rotational angular velocity of the laser emitter in the scan cycle T, and after the scan cycle ends, the laser emitter returns to the same position and pose as the scan cycle begins; a maximum detectable range of the Lidar is Dₘₐₓ; positions and poses of the reference point, the reference line, the reference plane, and the rotation axis on Lidar are all defined in an object coordinate system fixed on Lidar;

(2) selecting a positive integer K, and dividing a scan angle range [0,Φₘₐₓ] into K scan angle intervals [Φ₀, Φ₁], [Φ₁, Φ₂], [Φ_{K-1}, Φ_{K}], so that each horizontal scan angle interval is less than 180 degrees, where Φ₀=0, and Φ_{K}=Φₘₐₓ;

(3) starting a ranging simulation of Lidar in one horizontal scan cycle: assuming that a simulation moment at this time is tn_{T}, then for each simulation moment tₖ=tn_{T}+Φₖ/ω), where k∈{0, 1, . . . K−1}, the following processing is performed:

(3.1) calculating and updating positions and poses of Lidar and objects that can reflect lasers around Lidar at a moment tₖ;

(3.2) sampling object surfaces that can reflect lasers around Lidar, and generating a point set Bₖ through calculation, wherein for any sampling point q E Bₖ, the point q satisfies φ(q)∈[Φₖ,Φₖ₋₁], θ(q)∈[Θ₀, Θ_{NL-1}] and a distance between the reference point and the point q is less than or equal to Dₘₐₓ; wherein the point q is a nearest intersection point between R(q) and an object surface that can reflect lasers around Lidar, R(q) is a ray starting from the reference point and passing through the point q, φ(q) is an angle between the projection of R(q) on the reference plane and the reference line, and θ(q) is an angle between R(q) and the direction of the rotation axis;

(3.3) generating a two-dimensional data structure Cₖ having ML columns and NL rows, and initializing each element to a non-valid value, wherein ML is a smallest integer greater than or equal to ( ₖ₊₁−Φₖ)f/ω, and for each i∈{0, 1, 2 . . . ML−1}, elements in an i^{th} column of Cₖ are calculated through the following steps:

(3.3.1) when i is 0, directly performing step (3.3.2); when i is greater than 0, calculating and updating positions and poses of Lidar and objects that can reflect lasers around Lidar at a moment tₖ+i·f⁻¹;

(3.3.2) traversing each point q in Bₖ, calculating and updating the position of the point q at the moment tₖ+i·f⁻¹ according to a position and a pose of an object to which the point q belongs, and determining whether the point q satisfies the following conditions:

|φ(q)−Φₖ−(i/ML)(Φₖ₊₁−Φₖ)|≤δ1, (I)

|θ(q)−Θⱼⱼ|≤δ2, (II)

where δ1 is a first preset threshold, δ2 is a second preset threshold, Θ_{A} is a value closest to θ(q) in a sequence {Θ₀, Θ₁, Θ₂, . . . , Θ_{NL-1}}, and jj is a sequence number of the value in the sequence;

(3.3.3) if the point q satisfies both the conditions (I) and (II), updating an element Cₖ[i,jj] in an i^{th} column and a jj^{th} row of Cₖ with a distance between the reference point and the point q; if the point q does not satisfy both the conditions (I) and (II), checking whether a next point q satisfies the conditions (I) and (II);

(3.4) outputting data structures C₀, C₁, . . . , C_{K-1}, which are ranging simulation results of Lidar in the current scan cycle, wherein values stored in an element of an i^{th} column of a k^{th} data structure Cₖ are ranging simulation results of the NL laser emitters at a simulation moment tn_{T}+Φₖ/ω+i·f⁻¹;

(4) if the simulation does not reach an ending condition, performing step (3); otherwise, ending the simulation process.

Furthermore, each point in the point set Bₖ generated in the step (3.2) comprises position coordinates of the point in an object coordinate system of the object to which the point belongs, and information for directly or indirectly obtaining a position and a pose of the object to which the point belongs in the object coordinate system.

Furthermore, when the element Cₖ[i,jj] in the ith column and the jjth row of Cₖ is updated with the distance between the reference point and the point q in the step (3.3.3), the following updating rule is used: if Cₖ[i,jj] is the non-valid value set during initialization, then setting Cₖ[i,jj] to the distance between the reference point and the point q; if Cₖ[i,jj] is not the non-valid value set during initialization and the distance between the reference point and the point q is less than Cₖ[i,jj], then setting Cₖ[i,jj] to the distance between the reference point and the point q; if Cₖ[i,jj] is not the non-valid value set during initialization and the distance between the reference point and the point q is greater than or equal to Cₖ[i,jj], then checking whether the next point q satisfies the conditions (I) and (II).

The present disclosure has the following beneficial effects. According to the present disclosure, the motion of the laser radar and the motion of an object in the surrounding environment are fully considered in the simulation process. The motion of the laser radar itself not only includes the overall motion of the device, but also includes the rotary scanning motion of the laser emitter, so that accurate numerical simulation is provided.

Also, the amount of calculation is simplified by introducing a sampling point set, and the effect of improving the accuracy of simulation by using a small amount of calculation is achieved. The method is especially suitable for a scenario where the laser radar itself and/or surrounding objects are in a high-speed motion state, and can achieve a significantly higher simulation precision than that achieved by existing methods.

### BRIEF DESCRIPTION OF DRAWINGS

FIG. 1 is a schematic diagram of an object coordinate system of a laser radar;

FIG. 2 is a schematic diagram showing a positional relationship between the laser radar and a sampling point on a surrounding object;

FIG. 3 is a schematic diagram showing data associations between multiple types of texture images; and

FIG. 4 is a schematic diagram showing the effect of the laser radar simulation method proposed by the present disclosure.

### DESCRIPTION OF EMBODIMENTS

The objects and effects of the present disclosure will become more apparent from the following detailed description of the present disclosure made based on the accompanying drawings and preferred embodiments. It should be appreciated that the specific examples described herein are merely provided for illustrating, instead of limiting the present disclosure.

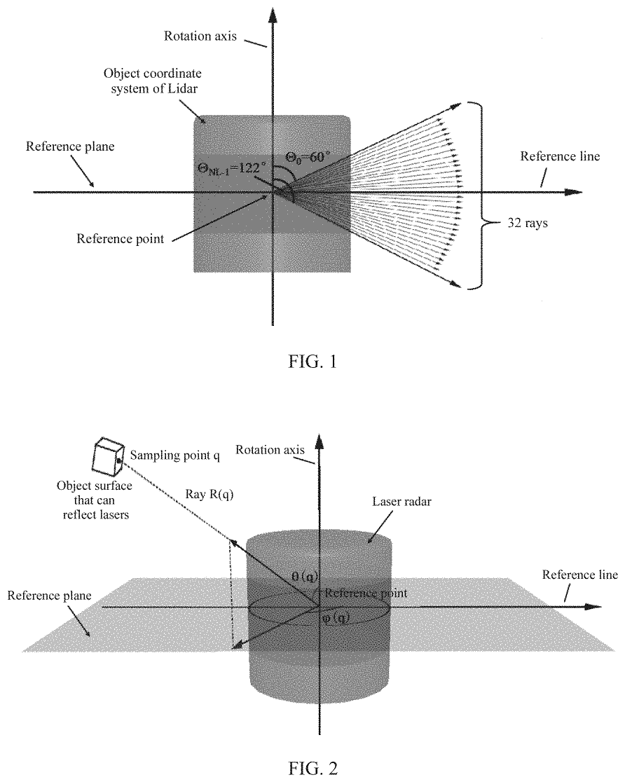

The present disclosure proposes a fast numerical simulation method for laser radar ranging considering a speed factor, including the following steps: (1) assuming that a horizontal scanning laser radar to be simulated is Lidar, as shown in FIG. 1 and FIG. 2, setting a working mode and parameters of Lidar as follows: a scan cycle of Lidar is 0.1 second; Lidar includes 32 laser emitters, and the laser emitters are configured to synchronously emit laser rays at a frequency f of 14400 Hz; each laser emitter emits one laser ray, and starting points of the beams are a same point on Lidar which is defined as a reference point; all the laser emitters are configured for fixed-axis rotation about a straight line passing through the reference point, and the straight line is defined as a rotation axis; a plane perpendicular to the rotation axis is a reference plane; the 32 laser rays emitted by the laser emitters at the same moment are located in a plane perpendicular to the reference plane; taking a direction in which the rotation axis points upward as a rotation axis direction, angles formed by the 32 laser rays and the rotation axis direction form an arithmetic sequence and are successively Θ₀=60°, Θ₁=62°, Θ₂=64°, . . . , Θ_{NL-1}=122°, where NL=32; projections of the laser rays emitted by Lidar when each scan cycle begins on the reference plane coincide with a ray emitted from the reference point, the ray emitted from the reference point is defined as a reference line, an angle by which the laser emitter rotate in a scan cycle of 0.1 second is Φₘₐₓ=360°, and a rotational angular velocity of the laser emitter is w=3600°/s; a maximum detectable range of Lidar is Dₘₐₓ=100 meters; rigid body motion of Lidar is represented by rigid body motion of the object coordinate system fixed on Lidar, rigid body motion of any object that can reflect lasers around Lidar is represented by rigid body motion of the object coordinate system fixed on the object, and related spatial coordinates are all measured in meters; positions and poses of the reference point, the reference line, the reference plane, and the rotation axis on Lidar are defined in an object coordinate system fixed on Lidar, as shown in FIG. 1; the shapes of the surfaces of all objects in the scene are described using triangular meshes;

(2) dividing a scan range [0°, 360° ] into 6 scan intervals [Φ₀, Φ₁],[Φ₁, Φ₂], . . . , [Φ₅,Φ₆], where Φ₀=0°, Φ₁=60°, Φ₂=120°, . . . , Φ₆=360°, and recording an angle range of each scan interval as ΔΦ=60°;

(3) starting a ranging simulation of Lidar in one horizontal scan cycle: assuming that a simulation moment at this time is tn_{T}, then for each simulation moment tₖ=tn_{T}+k/60, where k∈{0, 1, 2, . . . , 5}, performing the following processing:

(3.1) calculating and updating positions and poses of Lidar and objects that can reflect lasers around Lidar at a moment tₖ.

(3.2) obtaining sampling points on surfaces of objects that can reflect lasers around Lidar by three-dimensional graphics rendering, and generating a sampling point set Bₖ through calculation; FIG. 2 shows a positional relationship between the laser radar and a sampling point on a surrounding object; detailed sampling steps are as follows.

(3.2.1) setting the position of the reference point on Lidar at the moment tₖ to be a vector eye=[eyex,eyey,eyez], and setting the rotation axis direction of Lidar to be a vector up=[upx,upy,upz]; drawing a ray in the reference plane by using eye as a starting point, wherein an angle between the ray and the reference line is (2k+1)·ΔΦ/2; selecting a point center=[centerx,centery,centerz] on the ray, where a distance between center and eye is equal to the length of eye; constructing a view matrix Mᵥᵢₑ, required for 3D graphics rendering using a function gluLookAt(eyex,eyey,eyez,centerx,centery,centerz,upx,upy,upz) in the OpenGL function library;

(3.2.2) constructing a projection matrix Mₚᵣₒⱼ for 3D graphics rendering using a function glFrustum (left,right,bottom,top,near,far) in the OpenGL function library, where far is the maximum detectable range of Lidar, which is 100, near could be 0.1, left=−near·tan(ΔΦ/2), right=near·tan(ΔΦ/2), top=near·c tan(Θ₀), and bottom=near·c tan(Θ_{NL-1});

(3.2.3) setting camera observation projection parameters for 3D graphics rendering using the above M_{view} and Mₚᵣₒⱼ;

(3.2.4) creating a texture image Bₖ, which has 240 columns, 32 rows, and a pixel format of RGBA32; drawing triangular meshes one by one on the surfaces of the objects that can reflect lasers around Lidar by using a z-buffer hidden surface removal algorithm, and storing the rendering results in the texture image Bₖ; for any object rendered, representing its surface by a triangular mesh, wherein when rendering each triangle, the position of the coordinate system of the object to which each triangle belongs and the sequence number ID of the object to which the vertices belong are used as an attribute of each vertex and are passed to a GPU for computing; in the vertex shader calculation stage, calculating triangle vertex coordinates with the object's own model transformation and M_{view} matrix transformation and outputting the results to a position output channel and at the same time, passing the position of the vertex in the object coordinate system and the ID of the object to which the vertex belongs to the pixel shader; in the pixel shader calculation stage, writing the position of the object coordinate system of the vertex in the finally outputted RGB channel, and writing the ID of the object to which the vertex belongs in the finally outputted A channel. In the final rendering result, one pixel in the texture image Bₖ describes one sampling point on the surface of the object, and the following conditions are satisfied:

φ(q)∈[Φₖ,Φₖ₋₁], θ(q)∈[Θ₀, Θ_{NL-1}], and the distance between the reference point and the point q is less than or equal to Dₘₐₓ,

where the point q is a nearest intersection point between R(q) and an object surface that can reflect lasers around Lidar, R(q) is a ray starting from the reference point and passing through the point q, φ (q) is an angle between a projection of R(q) on the reference plane and the reference line, and θ (q) is an angle between R(q) and the rotation axis direction.

Moreover, for any pixel in the texture image Bₖ, position and pose information of the coordinate system of the object is obtained according to the sequence number ID, which is stored in the A channel, of the object to which the sampling point belongs, and then it can be learned that the information stored in the texture image Bₖ satisfies the following conditions:

each point generated in the point set Bₖ includes position coordinates of the point in an object coordinate system of the object to which the point belongs, and information for directly or indirectly obtaining a position and a pose of the object to which the point belongs in the object coordinate system.

(3.3) Creating a two-dimensional data structure Cₖ in the form of a texture image, which has ML=(Φₖ₊₁−Φₖ) f/ω=240 columns and NL=32 rows and a pixel format of R32, and is used for storing depth values; initiating all pixel values of Cₖ to a non-valid value 10⁸; for i∈{0, 1, 2, . . . , 239}, calculating the elements in the i^{th} column of Cₖ;

(3.3.1) when i is 0, directly performing step (3.3.2); when i is greater than 0, updating the position and pose of Lidar at a moment tᵢ=tₖ+i/14400, and then obtaining a view matrix M_{view} at the moment t₁ based on the method in step (3.2.1); updating the positions and poses of Lidar and objects that can reflect lasers around Lidar, and calculating a model transformation matrix of each object at the moment tᵢ; assuming that there are N objects in total, recording a model transformation matrix of the n^{th} object as MFₙ; storing the model transformation matrices corresponding to the N objects in a texture image Eₖ having N columns and 4 rows, where the pixel format of Eₖ is RGBA32, pixels in rows 0, 1, 2 and 3 of the n^{th} column of Eₖ store four row vectors of MFₙ respectively; establishing a lookup table VL for the sequence number ID of the object and the column position of the corresponding object transformation matrix in the texture image Eₖ;

(3.3.2) processing each pixel in Bₖ using the computer shader, and outputting the calculation result into the two-dimensional data structure Cₖ; for each pixel in Bₖ, executing the following steps:

(3.3.2.1) according to the sequence number ID of the object stored in the A channel of p, finding out the column position n of the corresponding model transformation matrix in the texture image Eₖ in the lookup table VL, and taking the pixels in rows 0, 1, 2 and 3 of the n^{th} column of Eₖ to form a model transformation matrix MFₙ;

(3.3.2.2) taking out a coordinate vector p.RGB stored in the RGB channel of p, and calculating a three-dimensional vector q=M_{view}·MFₙ·p·RGB, where q is the position of the sampling point corresponding to the pixel p at the moment L.

(3.3.2.3) calculating θ′=(90°−Θ₀)−arctan(q·y/q·z), and φ′=ΔΦ/2−arctan(q·x/q·z).

(3.3.2.4) calculating integer subscripts jj=round(32·θ′/(Θ_{NL-1}−Θ₀)) and ix=round(240·φ′/ΔΦ), where round represents a rounding function;

(3.3.2.5) if jj<0 or jj>=32 or if ix is not equal to i, ignoring the pixel p and returning to step (3.3.2.1) to continue to process the next pixel; assuming that a first preset threshold δ1 is (Φₖ₋₁−Φₖ)/ML=0.25°, and a second preset threshold δ2 is a tolerance of 2° between the 32 laser rays, it can be verified that if the pixel p is not ignored, the sampling point position q corresponding to the pixel p satisfies the following conditions:

|φ(q)−Φₖ−(i/ML)(Φₖ₊₁−Φₖ)|≤δ1, (I)

|θ(q)−Θⱼⱼ|≤δ2, (II)

where δ1 is the first preset threshold, δ2 is the second preset threshold, Θᵢᵢ is a value closest to θ (q) in a sequence {Θ₀, Θ₁, Θ₂, . . . , Θ_{NL-1}}, and jj is a sequence number of the value in the sequence;

(3.3.2.6) calculating a vector length |q| of q, and comparing the pixel value Cₖ[i,jj] in the i^{th} column and jj^{th} row of Cₖ with |q|: if |q|<Cₖ[i,jj], Cₖ[i,jj] in the i^{th} column and ii^{th} row of Cₖ is set to 141; otherwise, the pixel p is ignored and the process goes back to step (3.3.2.1) to continue to process the next pixel. It can be verified that the manner of updating the pixel values in Cₖ complies with the following updating rule:

if Cₖ[i,jj] is a non-valid value set during initialization, then setting Cₖ[i,jj] to the distance between the reference point and the point q; if Cₖ[i,jj] is not the non-valid value set during initialization and the distance between the reference point and the point q is less than Cₖ[i,jj], then setting Cₖ[i,jj] to the distance between the reference point and the point q; if Cₖ[i,jj] is not the non-valid value set during initialization and the distance between the reference point and the point q is greater than or equal to Cₖ[i,jj], then checking whether the next point q satisfies the conditions (I) and (II);

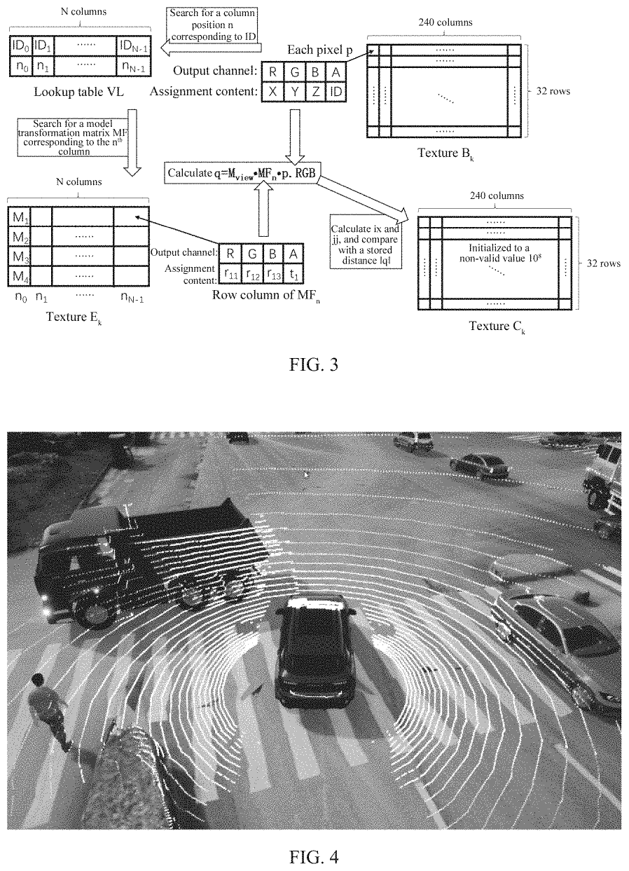

(3.4) outputting texture images C₀, C₁, . . . , C₅, which are ranging simulation results of Lidar in the current scan cycle, where values stored in the i^{th} column of elements of the k^{th} texture image Cₖ are a ranging simulation result obtained after the 32 laser emitters emit laser rays at a simulation moment t₁; the schematic diagram of the data associations between the texture images are as shown in FIG. 3;

(4) if the laser radar does not reach a preset simulation time or if the simulation program exits midway, proceeding to step (3); otherwise, ending the simulation process.

The final simulation result is as shown in FIG. 4, where a white point cloud in the scene is a radar scan simulation result of a vehicle in the center of the screen. In the figure, the truck on the left side of the screen and the vehicle in the center are both in motion. It can be seen that there is a certain displacement deviation between the position of the white point cloud formed by the scanning of the truck and the actual position of the truck. This is the simulation result formed by considering the relative movement of the vehicle and the rotation of the laser emitter, which is closer to an actual radar scanning process, exhibiting the beneficial effects of the present disclosure.

Those of ordinary skill in the art can understand that the above are only preferred examples of the present disclosure and are not intended to limit the present disclosure. Although the present disclosure has been described in detail with reference to the foregoing examples, those skilled in the art can still modify the technical solutions described in the foregoing examples, or make equivalent replacements to some of the technical features. Any modifications and equivalent improvements can be made thereto without departing from the spirit and principle of the present disclosure, which all fall within the protection scope of the present disclosure.

What is claimed is:

1. A fast numerical simulation method for laser radar ranging considering a speed factor, comprising the following steps:
(1) assuming a mechanical rotary laser radar to be simulated as Lidar, setting a working mode and parameters of Lidar as follows: Lidar comprises NL laser emitters, the laser emitters are configured to synchronously emit laser rays at a frequency f, each of the laser emitters emits one beam of laser ray, starting points of the beams are a same point on the Lidar which is defined as a reference point, all the laser emitters are configured for fixed-axis rotation about a straight line passing through the reference point, and the straight line is defined as a rotation axis; a plane perpendicular to the rotation axis is defined as a reference plane, and NL laser rays emitted by the laser emitters at a same moment are located in a plane perpendicular to the reference plane; a direction of either side of the rotation axis is taken as a rotation axis direction, and included angles formed by the NL laser rays and the rotation axis direction are successively Θ₀, Θ₁, Θ₂, . . . , Θ_{NL-1}, which satisfy Θ₁<Θⱼ, and 0<=i<j<NL; vertical projections of the laser rays emitted by Lidar at a starting moment of each scan cycle on the reference plane coincide with a ray emitted from the reference point, the ray emitted from the reference point is defined as a reference line, an angle by which the laser emitter rotate in a scan cycle T is Φₘₐₓ=ωT, where ω is a rotational angular velocity of the laser emitter in the scan cycle T, and after the scan cycle ends, the laser emitter returns to the same position and pose as the scan cycle begins; a maximum detectable range of the Lidar is Dₘₐₓ; positions and poses of the reference point, the reference line, the reference plane, and the rotation axis on Lidar are all defined in an object coordinate system fixed on Lidar;
(2) selecting a positive integer K, and dividing a scan angle range [0,Φₘₐₓ] into K scan angle intervals [Φ₀, Φ₁], [Φ₁, Φ₂], [Φ_{K-1}, Φ_{K}], so that each horizontal scan angle interval is less than 180 degrees, where Φ₀=0, and Φ_{K}=Φₘₐₓ;
(3) starting a ranging simulation of Lidar in one horizontal scan cycle: assuming that a simulation moment at this time is tn_{T}, then for each simulation moment tₖ=tn_{T}+Φₖ/ω, where k∈{0, 1, . . . K−1}, the following processing is performed:
(3.1) calculating and updating positions and poses of Lidar and objects that can reflect lasers around Lidar at a moment tₖ;
(3.2) sampling object surfaces that can reflect lasers around Lidar, and generating a point set Bk through calculation, wherein for any sampling point q∈Bₖ, the point q satisfies φ(q)∈[Φₖ,Φₖ₋₁], θ(q)∈[Θ₀, Θ_{NL-1}] and a distance between the reference point and the point q is less than or equal to Dₘₐₓ; wherein the point q is a nearest intersection point between R(q) and an object surface that can reflect lasers around Lidar, R(q) is a ray starting from the reference point and passing through the point q, φ(q) is an angle between the projection of R(q) on the reference plane and the reference line, and θ(q) is an angle between R(q) and the direction of the rotation axis;
(3.3) generating a two-dimensional data structure Cₖ having ML columns and NL rows, and initializing each element to a non-valid value, wherein ML is a smallest integer greater than or equal to (Φₖ₊₁−Φₖ)f/ω, and for each i∈{0, 1, 2 . . . ML−1}, elements in an i^{th} column of Cₖ are calculated through the following steps:
(3.3.1) when i is 0, directly performing step (3.3.2); when i is greater than 0, calculating and updating positions and poses of Lidar and objects that can reflect lasers around Lidar at a moment tₖ+i·f⁻¹;
(3.3.2) traversing each point q in Bₖ, calculating and updating the position of the point q at the moment tₖ+i·f⁻¹ according to a position and a pose of an object to which the point q belongs, and determining whether the point q satisfies the following conditions:

|φ(q)−Φₖ−(i/ML)(Φₖ₊₁−Φₖ)|≤δ1, (I)

|θ(q)−Θⱼⱼ|≤δ2, (II)
where δ1 is a first preset threshold, δ2 is a second preset threshold, Θⱼⱼ is a value closest to θ(q) in a sequence {Θ₀, Θ₁, Θ₂, . . . , Θ_{NL-1}}, and jj is a sequence number of the value in the sequence;
(3.3.3) if the point q satisfies both the conditions (I) and (II), updating an element Cₖ[i,jj] in an i^{th} column and a jj^{th} row of Cₖ with a distance between the reference point and the point q; if the point q does not satisfy both the conditions (I) and (II), checking whether a next point q satisfies the conditions (I) and (II);
(3.4) outputting data structures C₀, C₁, C_{K-1}, which are ranging simulation results of Lidar in the current scan cycle, wherein values stored in an element of an i^{th} column of a k^{th} data structure Cₖ are ranging simulation results of the NL laser emitters at a simulation moment tn_{T}+Φₖ/ω+i·f⁻¹;
(4) if the simulation does not reach an ending condition, repeating step (3); otherwise, ending the simulation process.

2. The fast numerical simulation method for laser radar ranging considering a speed factor according to claim 1, wherein each point in the point set Bₖ generated in the step (3.2) comprises position coordinates of the point in an object coordinate system of the object to which the point belongs, and information for directly or indirectly obtaining a position and a pose of the object to which the point belongs in the object coordinate system.

3. The fast numerical simulation method for laser radar ranging considering a speed factor according to claim 1, wherein when the element Cₖ[i,jj] in the i^{th} column and the jj^{th} row of Cₖ is updated with the distance between the reference point and the point q in the step (3.3.3), the following updating rule is adopted: if Cₖ[i,jj] is a non-valid value set during initialization, then setting Cₖ[i,jj] to the distance between the reference point and the point q; if Cₖ[i,jj] is not the non-valid value set during initialization and the distance between the reference point and the point q is less than Cₖ[i,jj], then setting Cₖ[i,jj] to the distance between the reference point and the point q; if Cₖ[i,jj] is not the non-valid value set during initialization and the distance between the reference point and the point q is greater than or equal to Cₖ[i,jj], then checking whether the next point q satisfies the conditions (I) and (II).
